(19) United States
(12) Patent Application Publication
(10) Pub. No.: US 2026/0006887 A1
(43) Pub. Date: Jan. 1, 2026

(54) HETEROGENEOUS INTEGRATED CIRCUIT

(71) Applicant: Massachusetts Institute of Technology, Cambridge, MA (US)

(72) Inventors: Tomas A. Palacios, Belmont, MA (US); Pradyot Yadav, North Wales, PA (US)

(21) Appl. No.: 19/256,826

(22) Filed: Jul. 1, 2025

Related U.S. Application Data
(60) Provisional application No. 63/666,318, filed on Jul. 1, 2024.

(51) Int. Cl. H10D 80/20; H01L 23/00; H01L 25/00; H01L 25/07; H01L 25/18; H10D 80/30

(52) U.S. Cl. CPC H10D 80/251; H01L 24/13; H01L 24/16; H01L 24/81; H01L 25/074; H01L 25/18; H01L 25/50; H10D 80/30; H01L 2224/13147; H01L 2224/16145; H01L 2224/81203; H01L 2924/10253; H01L 2924/1033; H01L 2924/13064; H01L 2924/13091

(57) ABSTRACT

Aspects of the present disclosure relate to a 3D-millimeter wave integrated circuit (3D-mmWIC configured to improve the efficiency and functionality of radio-frequency (RF) circuits through a multi-material, multi-layered architecture. These aspects can integrate silicon-based complementary metal-oxide semiconductor (CMOS) technology with other semiconductor materials, including Gallium Nitride (GaN), graphene, and/or various semiconductor alloys from the periodic table's Groups II-VI and/or III-V. The 3D-mmWIC can employ a layered structure comprising a silicon substrate, interleaved dielectric layers with embedded metal regions of varying thicknesses and lengths, a semiconductor layer, and/or additional oxide and dielectric layers. This architecture can enable the integration of multiple source, drain, and gate modules, interconnected via a sophisticated metal/oxide network. The disclosed integrated circuit architecture can provide significant advancements in RF circuit integration, offering reductions in size and cost while increasing design flexibility and performance.

### CROSS-REFERENCE TO RELATED APPLICATIONS

This application claims the benefit of priority to U.S. Provisional Patent Application No. 63/666,318, filed on Jul. 1, 2024, the entire content of which is hereby incorporated by reference in its entirety.

### FIELD

The present inventive concept generally relates to the fields of radio-frequency, microwave, sub-terahertz and terahertz frequency advanced circuit design, fabrication, and/or packaging.

### BACKGROUND

The Monolithic Microwave Integrated Circuit (MMIC) is a mainstay for III-V radiofrequency (RF) front ends, with applications ranging from telecom to defense. However, the present conventional monolithic, single III-V substrate approach, where all components, including interconnects, are fabricated simultaneously on a chip, such as those utilized for gallium nitride (GaN) devices, is large, and costly, hindering the widespread use of GaN as a result of its high cost and the challenges associated with its integration into conventional electronics.

Traditionally, GaN power amplifiers (PA) have set the benchmark for saturated output power at high-frequencies as compared to other technologies such as GaAs, SiGe, InP, LDMOS, and Si CMOS. Most GaN monolithic microwave integrated circuit (MMIC) processes are limited by the number and quality of available back-end-of-line (BEOL) layers. These layers are critical for the bias, matching, and control circuitry of the MMIC. Additionally, GaN MMIC processing is mostly limited to smaller wafer size (100 mm) foundries focused on GaN-on-SiC production. GaN-on-Si provides a cost-effective alternative to GaN-on-SiC, with recent demonstrations using gold-free metallization. For GaN to break into the $500 billion mobile market, a radical redesign to the MMIC process is needed. In contrast to GaN, Si CMOS benefits from advanced 300 mm BEOL. Furthermore, advanced multilayer passives have been developed with a smaller footprint compared to passives in GaN BEOL. Nevertheless, there remains a need for improved integrated circuits (ICs), and methods of fabricating such ICs that increase integration and reduce the size and cost of such devices.

### SUMMARY

Energy consumption of the world's communication networks exceeds 1% of the global energy production and it is increasing exponentially. In addition, by 2040 the amount of data generated will be at least 20× larger than what can be transmitted through this network. These two trends will dramatically change communication systems in the future. In order to revolutionize the future of RF front ends, a 3-Dimensional heterogeneous approach may need to be taken, which includes combining III—V based devices, such as GaN transistors, and silicon (Si) complementary metal-oxide semiconductors (CMOS). Leveraging the high-power amplification and high voltage switching of a GaN transistor will allow for high-density power RF and conversion systems and back-side power delivery, whereas a Si CMOS will enable bias, matching, and control circuitry. Aspects of the present inventive concept relate to a three-dimensional (3D)-millimeter wave integrated circuit (3D-mmWIC), that provides a significantly smaller RF chip footprint, a reduced cost in manufacture, and unprecedented design flexibility, and methods of fabricating the same.

According to an aspect of the inventive concept, provided is a method of fabricating an integrated circuit (IC).

According to another aspect of the inventive concept, provided is an integrated circuit fabricated by methods of the inventive concept.

According to another aspect of the inventive concept, provided is a method of fabricating a semiconductor device including an IC fabricated by method of the inventive concept.

According to another aspect of the inventive concept, provided is a semiconductor device including an IC of the inventive concept and fabricated by methods of the inventive concept.

### BRIEF DESCRIPTION OF THE DRAWINGS

Throughout the drawings, reference numbers can be re-used to indicate correspondence between referenced elements. The drawings are provided to illustrate embodiments of the present disclosure and are not intended to limit the scope of the inventive concept.

FIG. 1 illustrates a bird-eye view of a conventional Monolithic Microwave Circuit (MMIC).

FIG. 2 illustrates an enlargement of a single source, drain, and gate (S/D/G) module/GaN transistor, which may be one of a plurality of modules/transistors prepared on a large area wafer, and from which a single module/transistor may be acquired.

FIG. 3 illustrates a bird-eye view of a single S/D/G module/GaN transistor according to embodiments of the inventive concept.

FIG. 4 illustrates multiple metal layers of varying heights and widths stacked on top of one other, each embedded within dielectrics in an Si CMOS device.

FIG. 5 illustrates a cross-sectional view of a semiconductor device including an FEOL S/D/G module according to embodiments of the inventive concept hybrid-bonded to lower metal layers embedded in silicon.

FIG. 6 illustrates a cross-sectional view of a S/D/G module according to embodiments of the inventive concept hybrid-bonded to multiple metal layers, both top and above embedded in silicon.

FIG. 7 illustrates a cross-sectional view of an Si CMOS including multiple metal layers of varying thickness and width fabricated in Si.

FIG. 8 illustrates a cross-sectional view etched dielectric layers for pick-and-place source, drain, and gate modules.

FIG. 9 illustrates a cross-sectional view of dielectric bonding layer deposited in the etched dielectric pocket with embedded in metal layers of varying thickness and width fabricated in Si.

FIG. 10 illustrates a cross-sectional view of various sets of independent S/D/G modules embedded in pockets of oxides and bottom metal interconnects in etched metal pockets embedded in metal layers of varying thickness and width fabricated in Si.

FIG. 11 illustrates a bird's-eye view of various sets of independent source, drain and gate modules connected electrically in parallel via metal layers of varying thickness and width fabricated in Si.

FIG. 12 illustrates a cross-sectional view of top metal interconnect in dielectric layer formation on a device including various sets of independent S/D/G modules and oxides in etched metal pockets embedded in metal layers of varying thickness and width fabricated in Si.

FIG. 13 depicts a 3D-mmWIC integration platform for RF GaN dielets.

FIG. 14 depicts fabricated Gold-free AlGaN/GaN-on-Si HEMT. Panel a) Epitaxial layers of standard AlGaN/GaN-on-Si. Panel b) Tilted SEM image of fabricated 80 nm HEMT, with zoom of Cu-gate technology.

FIG. 15 depicts the dicing process of GaN-on-Si dielets. Panel a) Backside dicing scheme using femtosecond laser. Panel b) Fabricated 240 μm×410 μm dielet. Panel c) Side profile of dielet with 4° taper profile.

FIG. 16 depicts DC characteristics of L_{G}=80 nm HEMT Dielet. Panel a) I_{D}-V_{DS} characteristics of the fabricated 80 nm device Panel b) Regrown TLM contact resistance extraction of 0.22 Ω·mm is seen, with contact resistance breakdown by metal/n⁺⁺-GaN interfacial resistance, R₁, n⁺⁺-GaN resistance, R₂, and n⁺⁺-GaN/2DEG interfacial resistance, R₃ Panel c) Regrown TLM structure for contact resistance extraction. Panel d) ID-VGS characteristics of the device in log-scale. Panel e) DC transconductance is plotted against gate bias. Panel f) Small signal s-parameter measurements of dielets with pad de-embedding.

FIG. 17 depicts GaN dielet neutralization. Panel a) Optimum input and output conjugate impedance at 28 GHz. Panel b) Cross neutralization capacitance differential cell layout. Panel c) Simulated neutralization capacitance optimization at 28 GHz.

FIG. 18 depicts 3D-mmWIC circuit design. Panel a) Differential amplifier layout featuring cross-neutralization capacitance. Panel b) Differential amplifier layout without cross-neutralization capacitance. Panel c) Input balun EM model. Panel d) Output balun EM model. Panel e) Cross-neutralization capacitance path EM model. Panel (f) Neutralization capacitor EM model zoom, effective neutralization capacitance path value and delay.

FIG. 19 depicts the 3D integration scheme. Panel a) Cu—Cu bonding scheme. Panel b) Cross section scanning electron microscope (SEM) image of two dielets integrated with Si CMOS. Panel c) Cross section SEM of GaN and Si CMOS bonding interface with GaN FEOL and Si CMOS BEOL.

FIG. 20 depicts fabricated 3D-mmWIC amplifiers. Panel a) Intel 16 amplifier chips. Panel b) Single dielet integration into Si CMOS. Panel c) Two dielet integration into Si CMOS. Panel d) Four dielet integration into Si CMOS.

FIG. 21 depicts 3D-mmWIC Small Signal Measurements. Panel a) 3D-mmWIC without neutralization capacitance S-parameters. Panel b) 3D-mmWIC without neutralization capacitance stability results. Panel c) 3D-mmWIC with neutralization capacitance S-parameters. Panel d) 3D-mmWIC with neutralization capacitance stability results.

### DETAILED DESCRIPTION

The present inventive concept will now be described with reference to the following embodiments. As is apparent by these descriptions, this inventive concept can be embodied in different forms and should not be construed as limited to the embodiments set forth herein. Rather, these embodiments are provided so that this disclosure will be thorough and complete, and will fully convey the scope of the inventive concept to those skilled in the art. For example, features illustrated with respect to one embodiment can be incorporated into other embodiments, and features illustrated with respect to a particular embodiment can be deleted from that embodiment. In addition, numerous variations and additions to the embodiments suggested herein will be apparent to those skilled in the art in light of the instant disclosure, which do not depart from the instant inventive concept.

Unless otherwise defined, all technical and scientific terms used herein have the same meaning as commonly understood by one of ordinary skill in the art to which this inventive concept belongs. The terminology used in the description of the inventive concept herein is for the purpose of describing exemplary embodiments only and is not intended to be limiting of the inventive concept.

It will be understood that, although the terms “first,” “second,” “a),” “b),” etc. may be used herein to describe various elements, these elements should not be limited by these terms. These terms are only used to distinguish one element from another element. Thus, for example, a first element, a first component or a first section discussed herein could be termed a second element, a second component or a second section in some embodiments without departing from the teachings of the present inventive concept.

It will be understood that when an element such as a layer, region, or substrate is referred to as being “on” or extending “onto” another element, it can be directly on or extend directly onto the other element, or one or more intervening elements may also be present. In contrast, when an element is referred to as being “directly on” or extending “directly onto” another element, there are no intervening elements present. It will also be understood that when an element is referred to as being “connected” to another element, it can be directly connected to the other element or intervening elements may be present. In contrast, when an element is referred to as being “directly connected” to another element, there are no intervening elements present. Other words used to describe the relationship between elements should be interpreted in a like fashion (i.e., “between” versus “directly between”, “adjacent” versus “directly adjacent”, etc.). It will also be understood that the sizes and relative orientations of the illustrated elements are not necessarily shown to scale, and in some instances, the elements have been exaggerated for purposes of explanation.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used in the description of the inventive concept herein is for the purpose of describing particular embodiments and implementations only and is not intended to be limiting of the inventive concept. As used in the description of the inventive concept and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

The abbreviation, “e.g.” is derived from the Latin exempli gratia, and is used herein to indicate a non-limiting example. Thus, the abbreviation “e.g.” is synonymous with the term “for example.” No language in the specification should be construed as indicating any non-claimed element essential to the practice of the application.

As used herein the term “comprising” or “comprises” is used in reference to compositions, methods, and respective component(s) thereof, that are useful to an embodiment, yet open to the inclusion of unspecified elements, whether useful or not. It will be understood by those within the art that, in general, terms used herein are generally intended as “open” terms (e.g., the term “including” should be interpreted as “including but not limited to,” the term “having” should be interpreted as “having at least,” the term “includes” should be interpreted as “includes but is not limited to,” etc.).

The term “comprise,” as used herein, in addition to its regular meaning, may also include, and, in some embodiments, may specifically refer to the expressions “consist essentially of” and/or “consist of.” Thus, the expression “comprise” can also refer to, in some embodiments, the specifically listed elements of that which is claimed and does not include further elements, as well as embodiments in which the specifically listed elements of that which is claimed may and/or does encompass further elements, or embodiments in which the specifically listed elements of that which is claimed may encompass further elements that do not materially affect the basic and novel characteristic(s) of that which is claimed. For example, that which is claimed, such as a composition, construct, formulation, method, system, etc. “comprising” listed elements also encompasses, for example, a composition, construct, formulation, method, kit, etc. “consisting of,” i.e., wherein that which is claimed does not include further elements, and a composition, construct, formulation, method, kit, etc. “consisting essentially of,” i.e., wherein that which is claimed may include further elements that do not materially affect the basic and novel characteristic(s) of that which is claimed.

The term “about” generally refers to a range of numeric values that one of skill in the art would consider equivalent to the recited numeric value or having the same function or result. For example, “about” may refer to a range that is within ±1%, ±2%, ±5%, ±10%, ±15%, or even ±20% of the indicated value, depending upon the numeric values that one of skill in the art would consider equivalent to the recited numeric value or having the same function or result. Furthermore, in some embodiments, a numeric value modified by the term “about” may also include a numeric value that is “exactly” the recited numeric value. In addition, any numeric value presented without modification will be appreciated to include numeric values “about” the recited numeric value, as well as include “exactly” the recited numeric value. Similarly, the term “substantially” means largely, but not wholly, the same form, manner or degree and the particular element will have a range of configurations as a person of ordinary skill in the art would consider as having the same function or result. When a particular element is expressed as an approximation by use of the term “substantially,” it will be understood that the particular element forms another embodiment.

Traditional monolithic integrated circuits, such as monolithic microwave integrated circuits (MMICs), which may be primarily fabricated using single III-V substrate technologies, are typically characterized by large dimensions and high costs. These traditional designs often limit integration density and flexibility, which can be important for advancements in diverse applications from telecommunications to defense sectors. Such limitations hinder the progression towards more efficient and compact RF front-end designs, necessitating alternative approaches that can provide enhanced integration density, reduced manufacturing costs, and greater design flexibility. Some inventive concepts disclosed herein address these challenges by including a layered and integrated circuit architecture that can achieve significant improvements in power amplification, voltage switching, and overall circuit efficiency.

Some aspects of the inventive concept relate to heterogeneous integrated circuits, such as a 3D-millimeter wave integrated circuit (3D-mmWIC) that can integrate various semiconductor technologies into a unified architecture to enhance radiofrequency (RF) circuit functionalities. Aspects of the inventive concept can combine silicon-based complementary metal-oxide semiconductor (Si CMOS) technology with other semiconductor materials, including gallium nitride (GaN), graphene, and semiconductor alloys from Groups II-VI and/or III-V elements of the periodic table. The 3D-mmWIC architecture can include a substrate layer of silicon, followed by multiple dielectric layers embedding metal regions of variable thickness and length, a semiconductor layer, and additional layers of oxides and dielectrics. This configuration can facilitate the integration of various source, drain, and gate (S/D/G) modules, interconnected through a metal/oxide network, thereby improving the functional capabilities and efficiency of RF circuits.

Hereinafter, exemplary embodiments of the inventive concept will be explained in further detail with reference to the accompanying drawings.

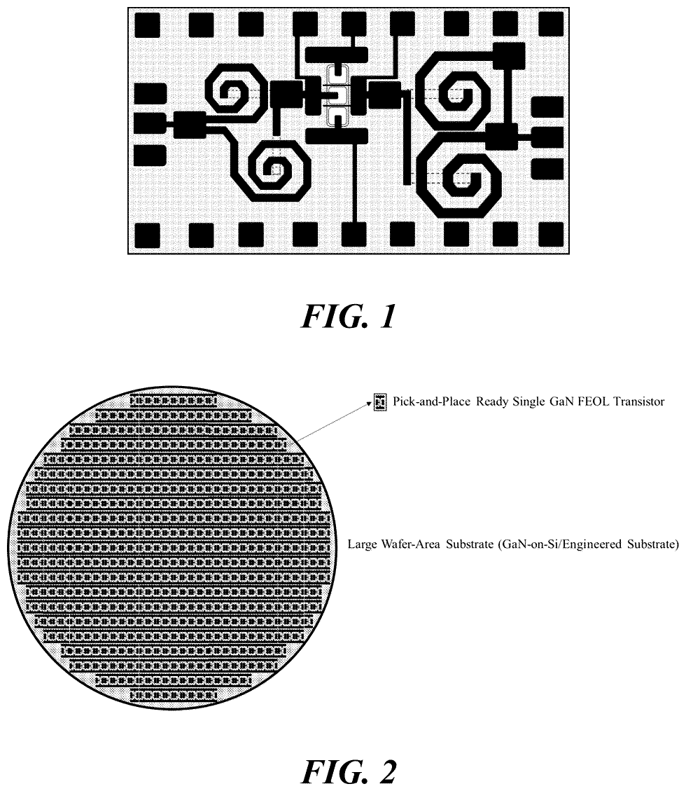

FIG. 1 depicts, in a bird-eye view, a conventional monolithic microwave integrated circuit (MMIC) with devices and electrical connections fabricated in a single compound semiconductor device. In the conventional MMIC, while the GaN transistor may map to only a small fraction of the total MMIC, additional structures and electrical connections are fabricated in the entire GaN wafer, and the integration with, e.g., an Si CMOS, utilizes the entire GaN wafer.

Referring to FIG. 2, a single S/D/G module, e.g., a pick-and-place ready single GaN FEOL transistor, that may be used in the methods and for fabricating devices according to embodiments of the inventive concept may be prepared, for example, as part of a plurality of modules/transistors on a large area wafer substrate. In some embodiments, a plurality of the S/D/G modules/transistors may be prepared on a GaN-on-Si/engineered substrate, and which may be diced apart into individual GaN-on-Si dielets, which may then be integrated with e.g., an Si CMOS.

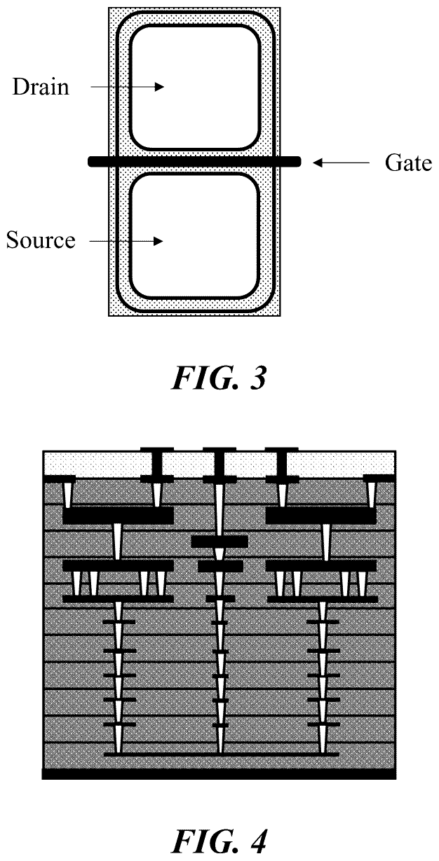

According to some embodiments, a single S/D/G module of the inventive concept may be, e.g., as illustrated in FIG. 3. The S/D/G module of the inventive concept, in some embodiments, may be a metal nitride device/transistor, such as a GaN FEOL device suitable for incorporation into a three-dimensional (3D)-millimeter wave integrated circuit (3D-mmWIC) according to embodiments of the inventive concept. In some embodiments, the S/D/G module may be a GaN transistor, such as a GaN high electron mobility transistor (HEMT). In some embodiments, the module may be a GaN-on-Si device, i.e., GaN grown on an Si substrate. The structure of the S/D/G module is not particularly limited. In some embodiments, the structure may be a module/transistor that includes a gate, and source and drain regions. The method of fabrication of S/D/G modules is also not particularly limited. In some embodiments, the S/D/G module may be fabricated in a manner including mesa isolation/etching. Multiple S/D/G modules may be fabricated, for example, using a stack, in some embodiments, an epitaxial stack, grown on a high-resistivity substrate, such as, but not limited to, an Si (111) substrate. An exemplary structure of the module may include, from bottom to top, a high resistivity Si substrate, a C-doped III nitride buffer layer, an unintentionally doped (UID) GaN layer, a spacer layer, and a barrier layer. In some embodiments, the spacer layer may include aluminum nitride (AlN). In some embodiments, the barrier layer may include aluminum gallium nitride (AlₓGa₁₋ₓN). In some embodiments, the aluminum gallium nitride layer may include Al_{0.25}Ga_{0.75}N. The dimensions/thicknesses of the layers in the devices of the inventive concept are not particularly limited, and layers included in the module/GaN device of the inventive concept may have any appropriate dimensions/thicknesses that will be appreciated by one of skill in the art. For example, the high resistivity Si (111) substrate may be about 200 mm in size and have a thickness of about 725 μm, the UID GaN layer may have a thickness of about 150 nm, and the barrier layer may have a thickness of about 18 nm.

Module/dielet fabrication may include formation of an ohmic contact, in which N⁺⁺—GaN is deposited to serve as the basis for source/drain regions. In some embodiments, the N⁺⁺—GaN may be deposited via molecular beam epitaxy (MBE). Metal contacts may be deposited on the source/drain regions. In some embodiments, the metal contacts may be e.g., of non-alloyed Ti (50 nm)/Al (150 nm). Mesa isolation may be performed to etch, e.g., 150 nm of the AlGaN/GaN structure. In some embodiments, the mesa isolation may be performed using Cl₂/BCl₃-based inductively coupled plasma-reactive ion etching (ICP-RIE). After this, pad metallization may be completed through deposition of, e.g., Ti (50 nm)/Al (150 nm), after which, Cu-gate fabrication may be performed. In some embodiments, Cu-gate fabrication may be performed using a 125 kV electron beam lithography (EBL) system configured to pattern a polymethyl methacrylate/methyl methacrylate (PMMA/MMA) resist bi-layer. Gate metal can be deposited using electron beam evaporation of, e.g., Ni (30 nm)/Cu (450 nm)/Ni (30 nm). The fabricated gate may have a gate length of about 80 nm, a stem height of about 350 nm, a total height of about 860 nm, and a width of about 812 nm. In some embodiments, plasma enhanced chemical vapor deposition (PECVD) may be used to form a 50 nm silicon nitride (SiN) passivation layer on the gate/AlGaN/GaN structure. Once fabrication is complete, a copper bump can be formed using electron beam evaporation of, e.g., Ti (100 nm)/Cu (1050 nm).

Multiple GaN-on-Si modules/dielets may then be separated by a dicing procedure, e.g., with a femtosecond laser with a 342 nm wavelength and 1.4 W power to singulate dielets fabricated on the wafer. Dicing may be performed on the back side of the substrate to protect the front side (S/D/G side) from debris. In some embodiments, the dielet/module dimensions may be, e.g., about 240 μm×about 410 μm, but not limited thereto. and the dielet/module dimensions may be of any appropriate size that may be appreciated by one of skill in the art. In some embodiments, the dielet area may be about 0.197 mm², but is not limited thereto. Modules/dielets prepared according to methods described herein may then be integrated with a CMOS, such as an Si CMOS, to provide the 3D-mmWIC according to embodiments of the inventive concept. In some embodiments, the modules/dielets and the CMOS of the inventive concept are integrated without the use of gold (Au). In some embodiments, the modules/dielets and the CMOS of the inventive concept are integrated using a Cu—Cu bonding scheme. In some embodiments, the total chip/IC area (dielet+CMOS) may be about 0.49 mm², but is not limited thereto.

According to some embodiments, an exemplary CMOS, such as, but not limited to, an Si CMOS, that may be implemented in embodiments of the inventive concept, i.e., for integration with the modules/dielets described herein may include, e.g., multiple dielectric layers, metal layers, and vias, for example, as depicted in FIG. 4. Metal layers/connectors may be disposed within dielectric layers of the CMOS, and may be connected by metal vias. Devices according to embodiments of the inventive concept may include a S/D/G module, such as a GaN-on-Si dielet, or multiple GaN-on-Si dielets, integrated with an Si CMOS, for example, as depicted in FIG. 4.

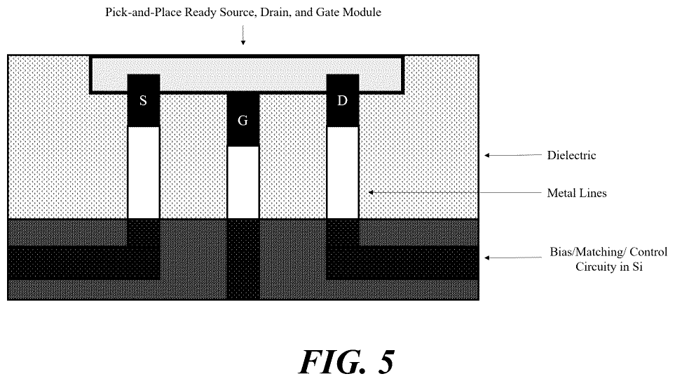

Referring to FIG. 5, an integrated device according to an embodiment of the inventive concept is depicted. In the integrated device, an S/D/G module, such as a pick-and-place ready module/transistor, is disposed on an Si CMOS, for example, on a dielectric layer including metal lines within the dielectric layer that connect the source, drain, and gate of the S/D/G module to bias/matching control circuitry within an Si layer disposed beneath the dielectric layer. The S/D/G module may be fabricated separately from the Si CMOS, and assembly of the integrated device may include placing the S/D/G module on the Si CMOS. The methods of placement of the S/D/G module on the Si CMOS are not particularly limited, and placement/mounting on and bonding to of the S/D/G module and the Si CMOS as depicted herein include, for example, surface mounting, e.g., surface mounting with a system suitable for performing surface-mount technology (SMT) component placement, such as with a pick and place system. Accordingly, the S/D/G module of the inventive concept, in some embodiments, may be a module that is pick-and-place ready, i.e., suitable for fabrication of a semiconductor device through surface mounting of an S/D/G module, such as a GaN transistor, on a CMOS, such as an Si CMOS. The S/D/G module may then be bonded to the Si CMOS by any method of circuit bonding that will be appreciated by one of skill in the art. such as thermocompression bonding (TCB).

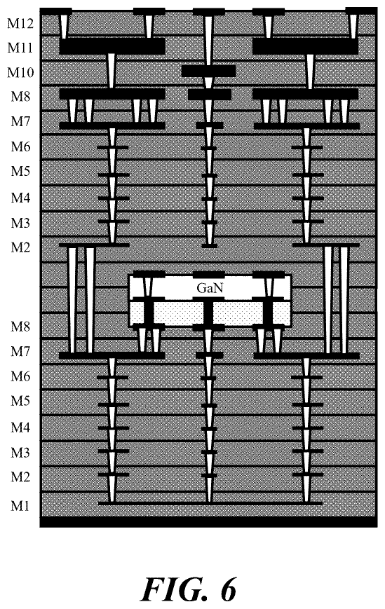

Referring to FIG. 6, a 3D-mmWIC device according to another embodiment of the inventive concept is shown. The 3D-mmWIC device as depicted in FIG. 6 includes a single S/D/G module, disposed/integrated within a stack of multiple dielectric layers, with dielectric layers disposed both below and above the S/D/G module.

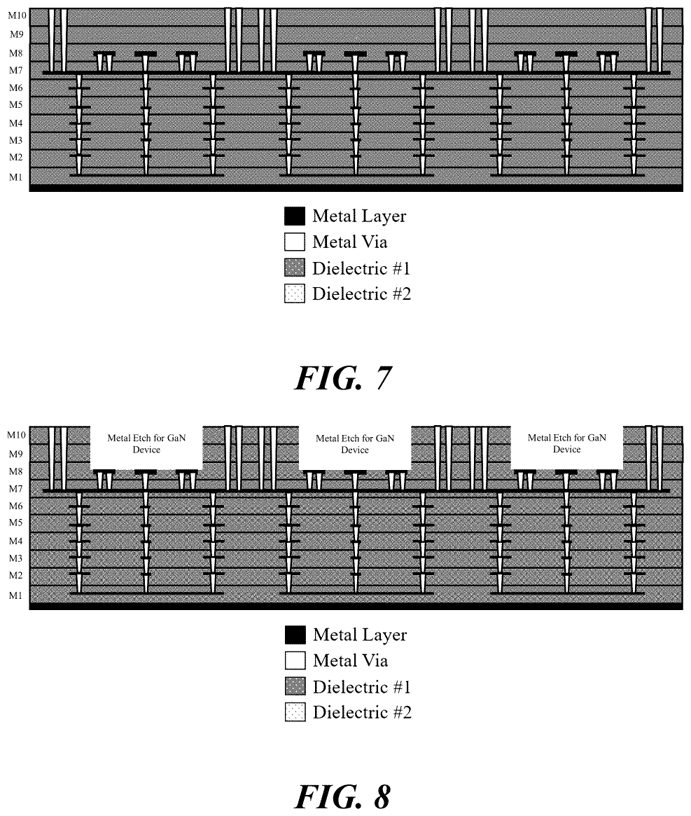

Referring to FIG. 7, a Si CMOS is depicted which may be prepared for integration with at least one module/dielet, i.e., a plurality of or multiple modules/dielets, as provided and fabricated as described herein. The Si CMOS may include multiple dielectric layers in which metal layers are disposed and which may be interconnected by metal vias. According to some embodiments, in the devices of the inventive concept, the metal routing, interconnects, and layers are generally provided/disposed in the CMOS, rather than on the GaN device side, such as is the case with a conventional GaN MMIC.

In some embodiments, fabrication of the 3D-mmWIC device may include etching the CMOS for placement of GaN devices, such as the GaN-on-Si modules/dielets described herein, an etched CMOS is exemplified in FIG. 8, wherein metal layers disposed within the dielectric layers are exposed and to contact with the modules/dielets are made.

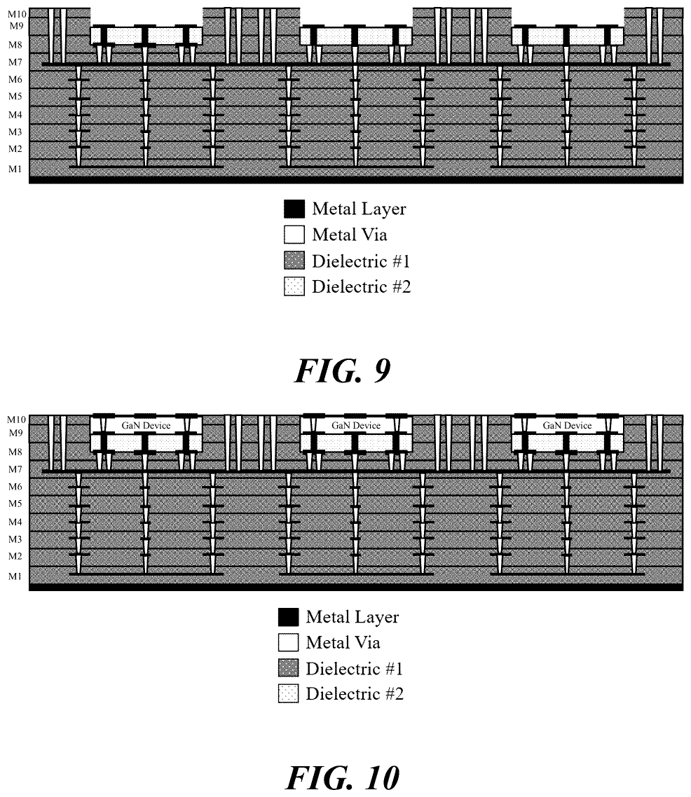

Referring to FIG. 9, in some embodiments, a dielectric bonding layer may be formed in the recesses provided by etching the CMOS as depicted in FIG. 8. In some embodiments, the dielectric bonding layer may include glass, however, the dielectric material is not limited thereto. Metal contacts may be disposed within the dielectric bonding layer and through which the modules/dielets are integrated with the CMOS.

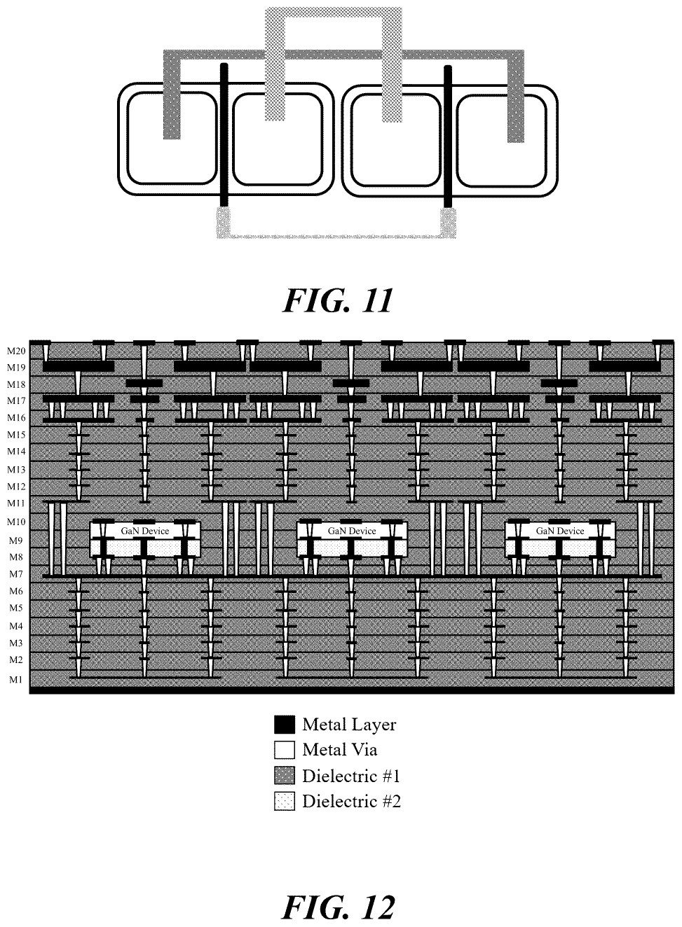

Referring to FIG. 10, the modules/dielets, such as the modules/dielets as described herein, may be integrated with the CMOS. Integration of the modules/dielets and the CMOS may include, e.g., metal-metal thermocompression bonding (TCB) of the GaN-on-Si modules/dielets described herein to the Si CMOS to provide the 3D-mmWIC. In some embodiments, the metal-metal TCB is an Au-free process, such as a Cu—Cu bonding scheme. The various source, drain, and gates of the GaN-on-Si modules/dielets are combined via metal lines in the Si CMOS to provide a device, e.g., as depicted in FIG. 11.

Following integration between GaN-on-Si modules/dielets and the Si CMOS, top dielectric and metal layers, interconnected with metal vias may be formed on top of/over the FEOL GaN-on-Si modules/dielets integrated with the CMOS BEOL

### Implementations

A first implementation of the inventive concept includes a 3D-matched gallium nitride device. Much like the conventional MMIC shown in FIG. 1, this example completes a typical GaN power amplifier but in a 3DHI manner, e.g., as shown in FIG. 3. The source, drain and gate modules exist in the GaN substrate. The bias network, matching network, stability network and DC blocking are implemented in an Si CMOS. This will allow for a significant reduction in chip size as the matching network can be implemented vertically, rather than laterally. The device is exemplified in FIG. 5.

A second implementation of the inventive concept includes a backside power delivery topology. High-speed GaN switching devices including a source, drain and gate module can be used to supply power to Si CMOS circuits. These embedded GaN devices can allow for power to be delivered from the backside of the circuit as opposed to the top. This allows for increased Si CMOS digital circuit density, increased power output and high-power delivery efficiency. Such devices are exemplified in FIGS. 5, 6, and 12.

A third implementation of the inventive concept includes a 3D-HI RF front end system. The amplification and power delivery will be completed in the GaN substrate via the various source, drain and gate modules. The FET of the LNA and PA will be represented by these devices. The electrical connections of the LNA and PA are implemented in an Si CMOS. The filter, mixer, local oscillator, ADC, and antenna array are implemented in Si CMOS.

The present invention is further exemplified in the following examples, which is intended to be illustrative only, since numerous modifications and variations therein will be apparent to those skilled in the art.

### EXAMPLES

Traditionally, GaN power amplifiers (PA) have set the benchmark for saturated output power at high-frequencies as compared to other technologies such as GaAs, SiGe, InP, LDMOS, and Si CMOS. Most GaN monolithic microwave integrated circuit (MMIC) processes are limited by the number and quality of available back-end-of-line (BEOL) layers. These layers are often important for the bias, matching, and control circuitry of the MMIC. Additionally, GaN MMIC processing is frequently limited to smaller wafer size (100 mm) foundries focused on GaN-on-SiC production. GaN-on-Si provides a potentially cost-effective alternative to GaN-on-SiC, with certain implementations demonstrating gold-free metallization. To address integration challenges and improve scaling opportunities, an alternative to the existing MMIC process is desirable. In contrast to GaN, Si CMOS benefits from advanced 300 mm BEOL. Furthermore, advanced multilayer passives have been developed with a smaller footprint compared to passives in GaN BEOL.

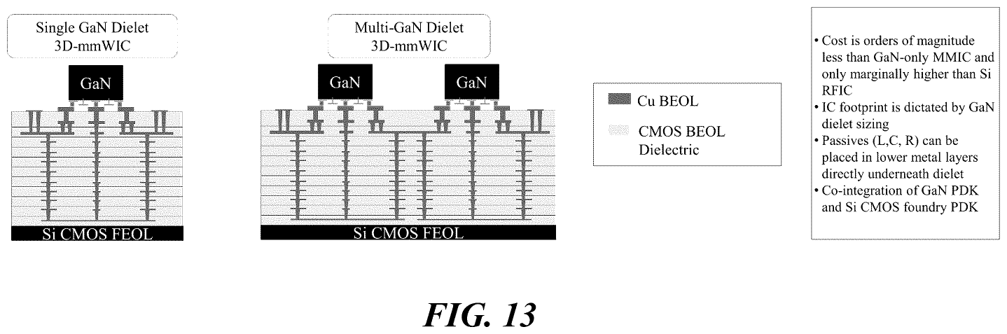

To support RF circuit design, Si CMOS and its BEOL can be leveraged with the high-power characteristics of the GaN HEMT. Work has been demonstrated on the development of a monolithic wafer-scale integration approach of GaN and Si CMOS. In spite of the functional results, this approach can result in area wastage on the GaN side. Although GaN transistors make up a small area of the total MMIC, an entire GaN wafer can be required for every Si CMOS wafer. The Si CMOS can utilize most of the chip area through BEOL fabrication. A solution to this problem can be dielet-scale integration of GaN and Si CMOS in which the entire GaN wafer is utilized. Prior efforts have focused on the 2.5D integration of GaN dielets into an interposer. Interposers can combine several technology nodes into a single package, but can be limited by non-Si CMOS BEOL and package parasitics. Previous works have integrated GaN dielets with Si CMOS using 3D Au—Au thermocompression bonding (TCB). However, metal routing was on the GaN dielet side, resulting in a large dielet size, increased cost, and Si CMOS foundry incompatibility. Gold-free 3D integration of GaN dielets with Si CMOS has not yet been widely demonstrated. GaN HEMT dielets have also been integrated with a Si wafer using metal-soldered bumps. Solder-based interconnects can be scaled to 10 μm pitch, while solder-free, metal-metal TCB can allow for sub-μm pitches. Some aspects of the inventive concepts described herein address limitations of previous 2.5D/3D integration approaches of GaN and Si CMOS and implements a modular, low-profile platform. The 3D-mmWIC integration platform is illustrated in FIG. 13. Through the 3D integration of 240 μm×410 μm gold-free GaN-on-Si HEMT dielets with Intel 16, a configuration for dielet-based RF front ends in Si CMOS is provided.

### 80 nm GaN-On-Si Dielet Technology

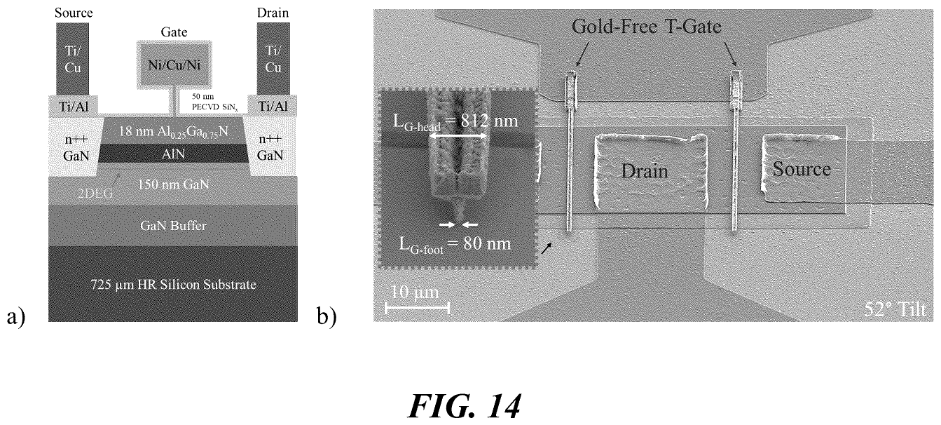

Some dielets described herein include an epitaxial stack as illustrated in FIG. 14, panel (a). An AlGaN/GaN-on-Si material composition can be formed on a 200 mm high-resistivity silicon substrate using metal organic chemical vapor deposition (MOCVD). The epitaxial stack can include a 725 μm high-resistivity Si (111) substrate, a C-doped Ill-nitride buffer layer, a 150 nm unintentionally doped (UID) GaN layer, an AlN spacer, and an 18 nm Al_{0.25}Ga_{0.75}N barrier layer. A sheet resistance (Rsh) can be approximately 300 Ω/□, with a carrier concentration of approximately 1.13×10¹³ cm⁻² and a charge mobility of approximately 1829 cm²/V·s.

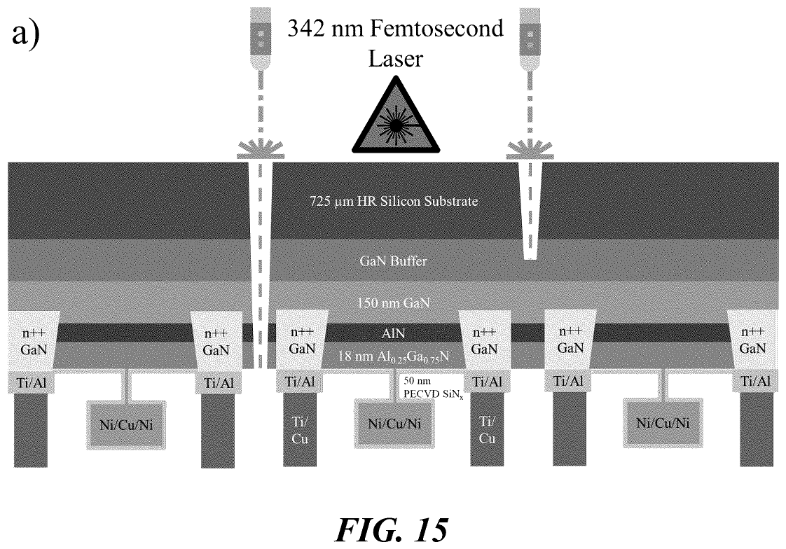

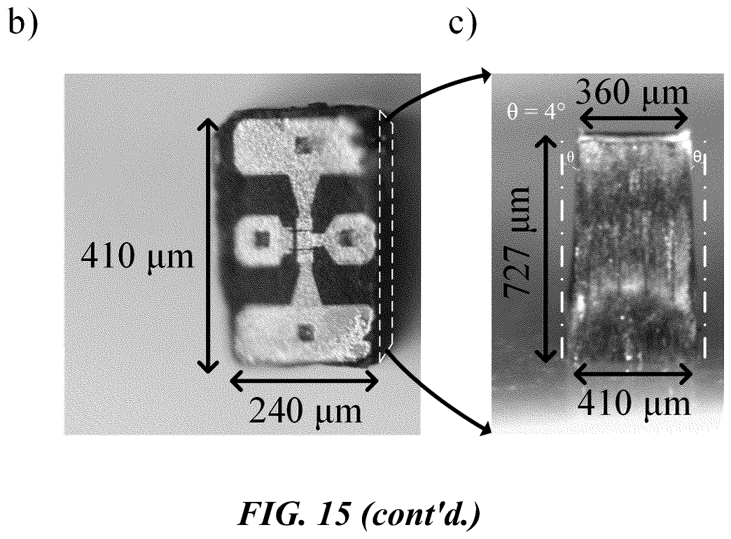

In some cases, dielet fabrication can include formation of the ohmic contact. An N⁺⁺—GaN layer can be deposited via molecular beam epitaxy (MBE). Non-alloyed Ti (50 nm)/Al (150 nm) metal contacts can be deposited using e-beam evaporation. Mesa isolation can be performed via a Cl₂/BCl₃-based inductively coupled plasma-reactive ion etching (ICP-RIE) process configured to etch approximately 150 nm of the AlGaN/GaN heterostructure. Pad metallization can be completed through the deposition of Ti (50 nm)/Al (150 nm). Cu-gate fabrication can be performed using a 125 kV electron beam lithography (EBL) system configured to pattern a polymethyl methacrylate/methyl methacrylate (PMMA/MMA) resist bi-layer. Gate metal can be deposited using electron beam evaporation of Ni (30 nm)/Cu (450 nm)/Ni (30 nm). The fabricated gate can have a gate length of approximately 80 nm, a stem height of approximately 350 nm, a total height of approximately 860 nm, and a width of approximately 812 nm, as shown in FIG. 14, panel (b). Plasma enhanced chemical vapor deposition (PECVD) can be used to form a 50 nm silicon nitride (SiN) passivation layer. Once fabrication is complete, a copper bump can be formed using electron beam evaporation of Ti (100 nm)/Cu (1050 nm). A femtosecond laser, such as an Innolas LINEXO system with a wavelength of approximately 342 nm and power of approximately 1.0 W, can be used to singulate the dielets from the wafer. Using alignment marks, dicing can be performed from the back of the sample (backside dicing) to protect the front side from material debris as shown in FIG. 15, panel (a). The thickness of the dielet can be less than 20 μm. The fabricated dielets can have a size of approximately 240 μm×410 μm, as shown in FIG. 15, panel (b). In some cases, a side profile of the dielet can include a 1° taper, as illustrated in FIG. 15, panel (c).

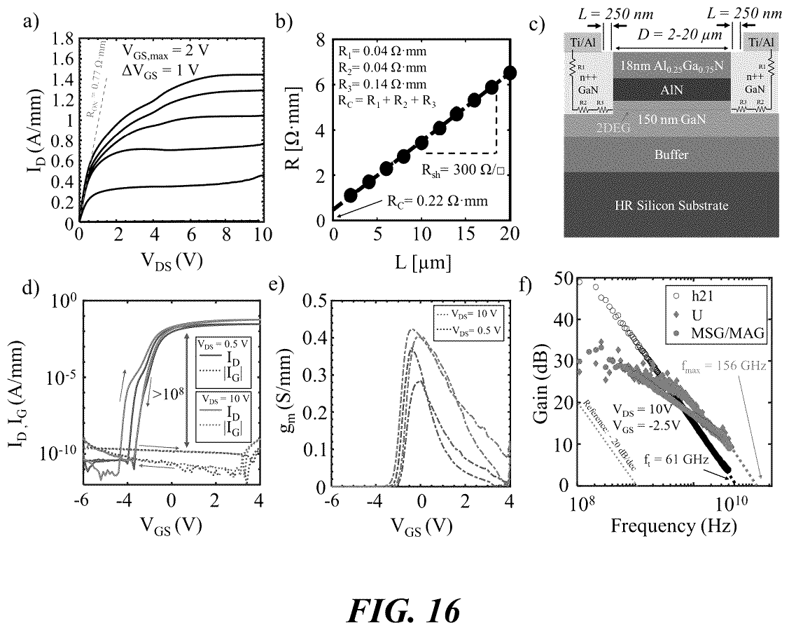

The DC and small-signal fₜ-fₘₐₓ characteristics of the 80 nm GaN technology can be represented as shown in FIG. 16. I_{D}-V_{DS} characteristics and the DC transconductance (gm) peak can be illustrated in FIG. 16, panel (a). An ON-OFF current ratio greater than 10⁵ can be obtained. FIG. 16, panel (d) illustrates an ON-OFF current ratio greater than 10⁵. A typical breakdown voltage can be approximately 22 V. A subthreshold slope (SS) of approximately 98 mV/dec can be extracted. The DC transconductance (gm) can be plotted as a function of gate bias, as shown in FIG. 16, panel (c), and a peak gm of approximately 420 mS/mm can be observed. Small-signal RF characteristics of the 80 nm technology node can be characterized using, for example, a Keysight PNA-X N5247B. Device pad parasitics can be extracted from the RF measurements using short and open de-embedding structures. The dielet can exhibit an fₜ/fₘₐₓ of approximately 61/156 GHz, as shown in FIG. 16, panel (f).

### Intel 16 Circuit Design

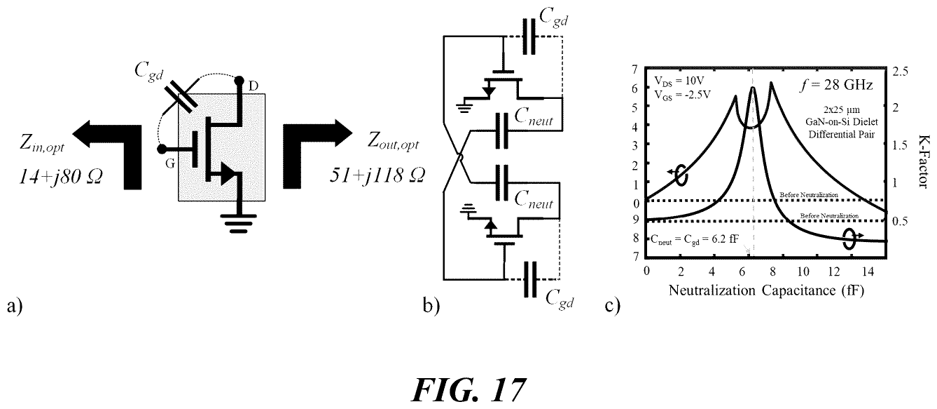

To support evaluation of dielet integration approaches, a traditional PA topology can be selected. A center frequency of 28 GHz can be used to target the 5G NR FR2 band. The ideal input and output impedance of the dielets can be determined and conjugate matching can be implemented to reduce the effects illustrated in FIG. 17, panel (a). The intrinsic gate-to-drain capacitance (Cgd) of the GaN dielet can be analyzed, where such capacitance can negatively affect power amplifier (PA) stability and gain. A cross-coupled neutralization capacitance (Cneut) can be applied, the value of which can be set approximately equal to the gate-to-drain capacitance of the GaN dielets, such that the effect of the intrinsic Cgd can be suppressed. A circuit schematic illustrating this technique is shown in FIG. 17, panel (b). Use of this technique can provide enhanced stability, gain, and tolerance to dielet process variation. While this approach can be used in CMOS design, it has limited implementation in GaN MMIC processes due to BEOL metal-tracker constraints. A neutralization capacitance (Cntrl) can be implemented for a 2×25 μm dielet at 28 GHz, and a value of approximately 5.2 fF can be used. By applying this capacitance, as shown in FIG. 17, panel (c), a gain improvement of approximately 4.5 dB and a K-factor stability increase of approximately 1.5 at 28 GHz can be achieved.

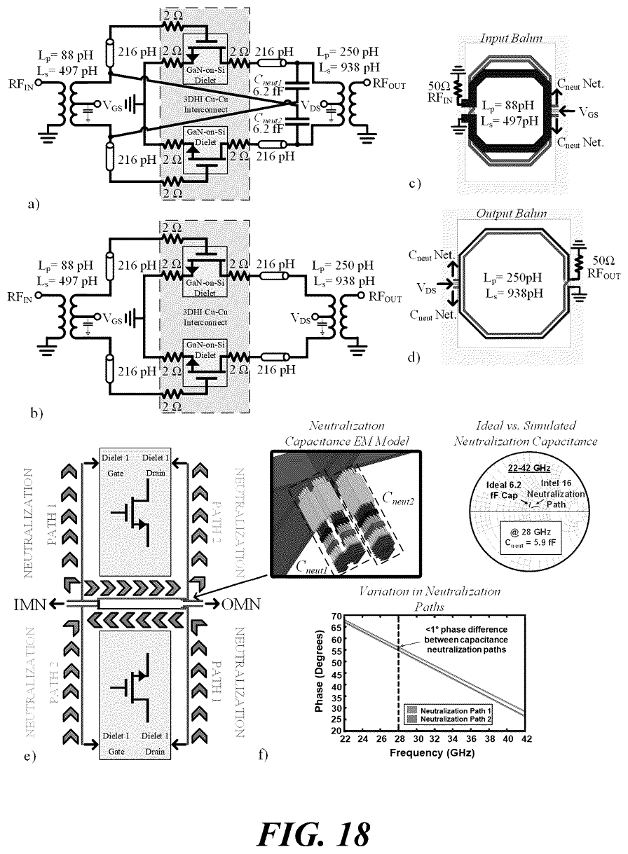

Amplifier schematics can be illustrated in FIG. 18, panel (a) and panel (b). The layout in FIG. 18, panel (a) can include an optimized cross-neutralization capacitance, while the layout in FIG. 18, panel (b) can omit the neutralization scheme to allow comparison of configurations with and without the capacitance. Both amplifiers can share the same input and output balun. FIG. 18, panel (c) and panel (d) illustrate structures that provide both impedance matching and thermal management for the dielets. The implemented neutralization capacitance can be formed using a series transmission line, resulting in an effective neutralization capacitance of approximately 5.9 fF due to added inductance, as shown in FIG. 18, panel (d). Both neutralization paths can exhibit minimal difference in electrical length, with less than one degree of phase delay variation between them. Off-chip DC blocks can be used. The dielets can be mounted using 12 μm copper pads provided by the foundry to support 3D heterogeneous integration (3DHI) with the dielets. The 3D Cu—Cu interconnects can be modeled primarily by their parasitic resistance.

### 3DHI and 3D-mmWIC Fabrication

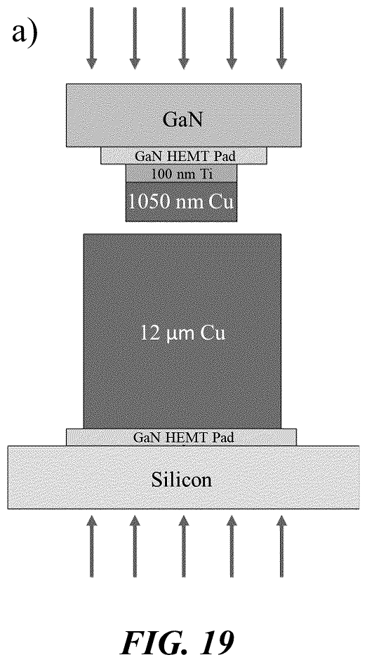

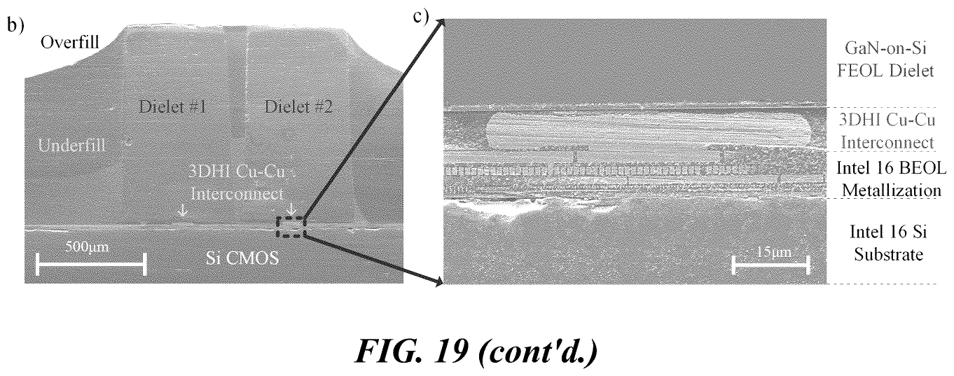

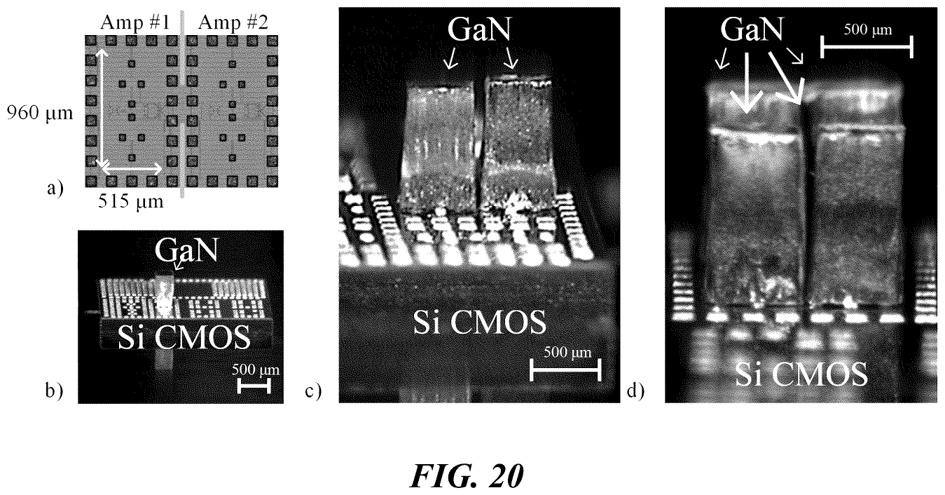

After fabrication of the dielets and Si CMOS circuits, integration can be performed via direct Cu—Cu thermocompression bonding (TCB), as illustrated in FIG. 19, panel (a). Bonding can be carried out using a Finetech FINEPLACER Sigma system operating within a formic acid environment at approximately 350° C. and applying a force of approximately 2 N. FIG. 19, panel (b) and FIG. 19, panel (c) illustrate the integration of the dielets with the Si CMOS. Tight dielet spacing can be achieved using interconnects with a 10 μm pitch. A seamless metal interface can be formed between the GaN dielet and the Si CMOS. The copper interconnect on the GaN dielet can measure approximately 25×25×1 μm³, and the copper interconnect on the Si CMOS side can measure approximately 55×55×12 μm³. Variation in alignment tolerance (μ) and interconnect volume can be used to facilitate successful Cu—Cu bonding alignment. Using this integration approach, dielets can be mounted on Intel 16 amplifier chips. Each amplifier can occupy an area of approximately 1.15 mm×0.90 mm. The dielet footprint can be approximately 240 μm×890 μm. This configuration can allow for utilization of both the GaN and Si CMOS substrate areas. Fabricated 3D-mmWIC amplifiers are shown in FIG. 20.

### Measurements

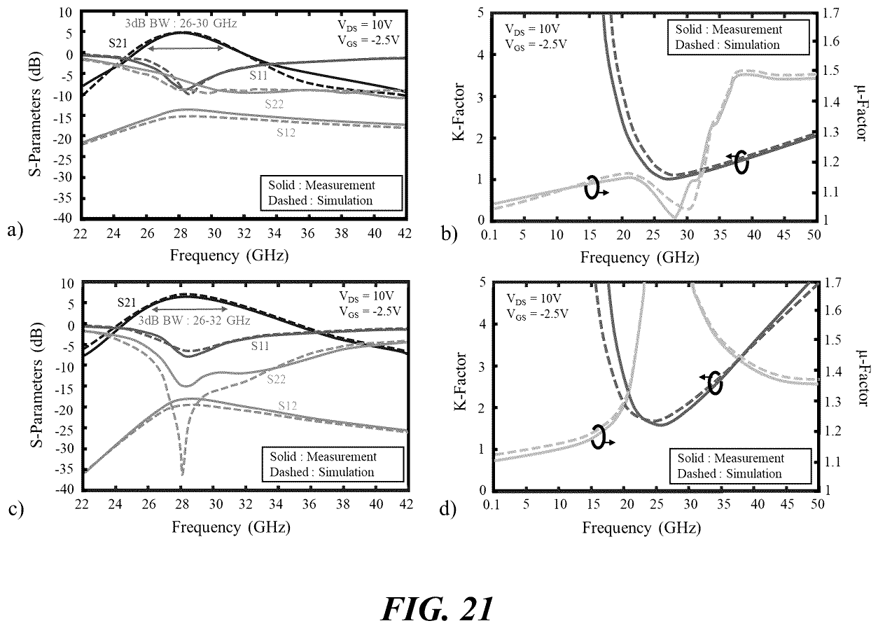

The fabricated GaN/Si CMOS 3D-mmWICs can be characterized using DC IV checks and small-signal S-parameters, as shown in FIG. 21. A bias of Vgs=10 V and Vds=−2.5 V can be applied for both amplifiers. The amplifier without neutralization capacitance can exhibit a peak gain of approximately 4.8 dB with a 3 dB bandwidth of 26-30 GHz. The K-factor can remain greater than 1 over the entire measurement sweep, with μ-factor greater than 1. The amplifier with neutralization capacitance can exhibit a peak gain of approximately 6.2 dB with a 3 dB bandwidth of 26-32 GHz. The K-factor can be greater than 1.5 over the entire measurement sweep, with μ-factor greater than 1.1. Other GaN/Si CMOS IC configurations are summarized in Table I. When compared to previously reported 2.51D and 3D) integration technologies, the 3D-mmWGC configuration described herein can support integration of GaN-on-Si dielets with Si CMOS chips at the single transistor level using gold-free 3D interconnects. Large-signal measurements can be performed following suppression of leakage attributed to the SiN PECVD passivation layer used in the dielet technology. This leakage is not a result of the 3D integration approach, and as such does not affect the feasibility of the 3D-mmWIC concept.

| | This work | IMS2024 | RFIC2024 | RFIC2015* |
|---|---|---|---|---|
| Topology | Single Stage | Single Stage | Single Stage | Two Stage |
| | Differential | | Differential | |
| GaN Technology | 80 nm | 80 nm N-Polar | 80 nm N-Polar | 200 nm |
| | GaN-on-Si | GaN-on-SiC | GaN-on-SiC | GaN-on-SiC |
| Si Interposer/Si | 11-Metal Layer | 4-Metal Layer Si | 4-Metal Layer Si | 10-Metal Layer |
| Technology | Intel 16 | Interposer | Interposer | IBM 10LPe |
| Passives Locations | Si CMOS | Si Interposer | Si Interposer | GaN-on-SiC |
| Interconnect Type | 3D Cu—Cu | 2.5D Metal | 2.5D Metal | 3D Au—Au |
| | TCB | Interconnect | Interconnect | TCB |
| V_{DS} (V) | 10 | 8 | 20 | 28 |
| Peak Gain (dB) | 6.2 | 8.0 | 6.5 | 15 |
| 3 dB BW (GHz) | 26-32 | 24-29 | 26-31 | 32-40 |
| Pₛₐₜ (dBm) | 21 | 19.8 | N/A | 27 |
| PAE (%) | 26 | 23.5 | NA | 20 |
| Number of Dielets | 1, 2, 4 | 1 | 1 | 1 |
| Au- Free | Yes | No | No | No |
| Total Chip Area | 0.49 | 0.79 | 0.99 | 3.74 |
| (mm²) | | | | |
| Total Dielet Area | 0.197 | 0.058 | 0.156 | 2.965 |
| (mm²) | | | | |

### CONCLUSION

Aspects and implementations of the inventive concepts described herein relate to a low-cost 3D heterogeneous integration (3DHI) platform for RF applications, sometimes referred to as 3D-mmWIC. 80 nm gold-free GaN-on-Si dielets having a size of about 240 μm×410 μm can be integrated using Cu—Cu thermocompression bonding (TCB) with Intel 16 Si CMOS. In some examples, the integration approach can include a gold-free 3DHI process incorporating multiple GaN-on-Si dielets. The configuration can combine device engineering, Si CMOS foundry-compatible circuitry, and 3D packaging techniques to support compact RF power amplifier implementations within existing semiconductor infrastructure. Both a 26-30 GHz 3D-mmWIC and a 26-32 GHz 3D-mmWIC incorporating a feed-forward cross-neutralization scheme can be fabricated. In some cases, the described approach can support RF scaling in three dimensions, and can facilitate extended integration of GaN with Si CMOS to improve circuit density and performance.

The foregoing is intended to be illustrative of the present invention and is not to be construed as limiting thereof. The invention is defined by the following claims, with equivalents of the claims to be included therein.

What is claimed is:

1. A heterogeneous microwave integrated circuit, comprising:
a metal nitride-on-dielectric stack comprising a source, drain, and gate; integrated with
a complementary metal-oxide semiconductor (CMOS),
wherein the CMOS comprises at least one dielectric layer with embedded metal regions of varying thickness and lengths.

2. The integrated circuit of claim 1, further comprising at least one further layer fabricated on top of the metal-nitride-on dielectric stack.

3. The integrated circuit of claim 1, wherein the metal nitride comprises gallium nitride (GaN).

4. The integrated circuit of claim 1, wherein the dielectric comprises silicon (Si).

5. The integrated circuit of claim 4, wherein the Si of the dielectric comprises Si (111).

6. The integrated circuit of claim 1, wherein the metal nitride comprises a Group III-V metal.

7. The integrated circuit of claim 6, wherein the Group III-V metal is gallium (Ga).

8. The integrated circuit of claim 1, wherein the CMOS is an Si CMOS.

9. The integrated circuit of claim 1, wherein the metal nitride-on-dielectric stack is integrated to the CMOS with gold (Au)-free interconnects.

10. The integrated circuit of claim 1, wherein the metal nitride-on-dielectric stack is integrated with the CMOS through copper (Cu) interconnects.

11. A method of fabricating a heterogeneous integrated circuit (IC) comprising:
depositing a C-doped III-nitride buffer layer on a substrate;
depositing an unintentionally doped (UID) metal nitride layer on the buffer layer;
depositing a spacer layer on the UID metal nitride layer;
depositing a metal nitride barrier layer on the spacer layer;
forming source and drain terminals; and
forming a gate on the spacer layer,
to provide IC component, and
integrating the IC component with a CMOS to provide the heterogeneous IC.

12. The method of claim 11, wherein the CMOS comprises an Si CMOS.

13. The method of claim 11, wherein the C-doped III-nitride layer and/or the UID metal nitride layer comprise GaN.

14. The method of claim 11, wherein the spacer layer comprises aluminum nitride (AlN).

15. The method of claim 11, wherein the metal nitride layer on the spacer layer comprises AlₓGa₁₋ₓN.

16. The method of claim 11, wherein integrating the IC component comprises forming a gold (Au)-free interconnect between the IC component and the CMOS.

17. The method of claim 16, wherein the interconnect comprises a copper-copper (Cu—Cu) interconnect.

18. The method of claim 11, wherein the providing the IC component comprises dicing a plurality of IC components fabricated on a substrate into individual dielets, wherein the individual dielets comprise the IC component.

19. A radio-frequency (RF) IC comprising;
a GaN-on-Si stack comprising a source, drain, and gate; integrated with
an Si CMOS,
wherein the GaN-on-Si stack interconnect with the Si CMOS via a Cu—Cu interconnect.

20. The RF IC of claim 19, wherein the GaN-on-Si stack is formed on high resistivity Si (111).
